(19) United States
(12) Patent Application Publication
(10) Pub. No.: US 2026/0181233 A1
(43) Pub. Date: Jun. 25, 2026

(54) MULTIFUNCTIONAL MOBILE MODULE FOR AUTOMATIC VEHICLE CONTROL

(71) Applicants: Dmitriy Andreevich Petrulevich, Moscow (RU); Oleg Vladimirovich Pryalukhin, Korolev (RU); Dmitriy Mikhaylovich Molchanov, Moscow (RU); Ilya Mihajlovich Fedichev, Moscow (RU); Oleg Sergeevich Shipitko, Moscow (RU); Andrey Sergeevich Bolshakov, Moscow (RU); Anton Dmitrievich Poppel, Moscow (RU); Dmitriy Sergeevich Kolesnikov, Moscow (RU)

(72) Inventors: Dmitriy Andreevich Petrulevich, Moscow (RU); Oleg Vladimirovich Pryalukhin, Korolev (RU); Dmitriy Mikhaylovich Molchanov, Moscow (RU); Ilya Mihajlovich Fedichev, Moscow (RU); Oleg Sergeevich Shipitko, Moscow (RU); Andrey Sergeevich Bolshakov, Moscow (RU); Anton Dmitrievich Poppel, Moscow (RU); Dmitriy Sergeevich Kolesnikov, Moscow (RU)

(21) Appl. No.: 19/125,475

(22) PCT Filed: Dec. 20, 2023
(86) PCT No.: PCT/RU2023/050302

§ 371 Date: Apr. 29, 2025

(30) Foreign Application Priority Data
Dec. 28, 2022 (RU) 2022134747

(51) Int. Cl. H04N 23/54; H04N 23/45; H05K 7/20

(52) U.S. Cl. CPC H04N 23/54; H04N 23/45; H05K 7/20736

(57) ABSTRACT

The objective of the proposed invention is to make it possible to mount the multifunctional mobile module onto the roof of any vehicle to turn it into an autonomous vehicle by providing all the functions of an autopilot system within a single module, ensuring the operability of the module within a wide range of ambient temperatures (−40° C. to +50° C.), as well as within a wide range of weather conditions (rain, downpour, snow) by means of a thermal management system (TMS) and sensor cleaning systems that are integrated into the body of the module.
The multifunctional mobile module for automatic vehicle control comprises an underframe made of a metal profile and equipped with metal brackets that hold screw-connected sensors (cameras, a lidar, an inertial navigation system, a Global Navigation Satellite System (GNSS) receiver), equipment (calculators, fans, heaters, network switches, a peripherals controller, GSM (Global System for Mobile Communications) antennas, sensor cleaning system components), and an outer plating that is also mounted onto the underframe.

### FIELD OF INVENTION

The present invention relates to the field of autonomous vehicles, particularly to multifunctional mobile modules that enable an autopilot system to function.

### DESCRIPTION OF THE RELATED ART

There are various vehicle systems using cameras, lidars and other sensors known in the art. For instance, there is a sensor module disclosed in US 2022111801 A1, IPC: B60R11/04, made public on Apr. 14, 2022, which is a multi-purpose perception housing that may include cameras and/or other sensors. The housing assembly can be mounted on a roof of a vehicle, such as a semi-trailer truck.

The drawbacks of this solution include the lack of a finite set of sensors that will be installed in the enclosure, as well as the lack of computing equipment inside the enclosure. The housing does not have any sensor cleaning systems, and it is also not possible to mount it on a roof of any vehicle.

Another international application (WO 2021137884 A1, IPC: B60W10/18, B60W10/20, B60W40/02, B60W40/105, B60W60/00, G01D11/24, G05D1/02, made public on Jul. 8, 2021) discloses a set of guidelines on making an autonomous vehicle, particularly describes various options of positioning sensors along the perimeter of different vehicles and integrating said sensors into housings that would include cameras, radars, and lidars. In particular, a rooftop housing, a housing at the front end of the vehicle, two housings on the sides of the vehicle towards the rear part and two more housings on the sides towards the hood are used. In addition, the application contains information on modifications that a vehicle needs, as well as on the general principles of controlling an autonomous vehicle.

The drawback of this solution is that all the disclosed housings have to be redesigned to be able to integrate into a specific vehicle type. The proposed set of sensors would require enormous computing power in order to process data from the sensors. The housings of the modules do not have sensor cleaning systems, whereas some of them are located in areas where they can become dirty very quickly. Because there are several individual modules, it is impossible to mutually pre-calibrate the sensors.

Yet another system is known from CN 113677565 A, IPC: B60R11/04; B60W30/10; G01S13/86; G01S17/87; G01S17/89, made public on Nov. 19, 2021, which is a side mirror assembly of a tractor-trailer that comprises a narrow field camera in a direction opposite a forward travel direction of the vehicle; a second camera having a field of view in a forward driving direction of the vehicle; and a third camera having a field of view in a direction perpendicular to a forward travel direction of the vehicle, and down. The uninterrupted camera field of view spans at least 180°. Also, the side mirror assembly further comprises at least one radar sensor, one lidar sensor, and an Inertial Measurement Unit (IMU). The sensor assembly further comprises an arm assembly configured to project the side mirror assembly outwardly from the vehicle. The rear part of the assembly is a rear-view mirror for the driver.

The drawback of this solution is that the disclosed assembly has a specific design that can be mounted only on certain truck models. The disclosed assembly does not contain any computing equipment and cannot be used separately from the vehicle that has additional computing capacities on board. Also, the assembly does not have any systems for cleaning the sensors, which will inevitably become dirty. Because the central camera is strongly inclined downward, the cameras have a reduced field of view sideways. Separation of the right module and the left module makes it impossible to mutually pre-calibrate their sensors.

There are conventional autonomous cars with on-roof modules that are equipped with a radar, lidar, and cameras on each side of the car, as well as with inertial sensors and a GNSS receiver (see https://smartcar.starline.ru/bespilotnie-avtomobili-dla-nachinajushih/?ysclid=l9zn0nzbrp3973689).

The drawbacks of this car design include the fact that the disclosed modules can be mounted only on cars, and all the sensors are located separately on the roof instead of in the module itself, while all the computing equipment is located inside the car, and also the car roof has to be partially dismantled in order to mount the module, which makes it difficult to mount.

The closest prior art is a mobile module housing for an autonomous vehicle disclosed in RU 205648 U1, B60W 60/00, made public on Jul. 26, 2021, which comprises an upper casing and a lower casing with a framework of aluminum pipes rigidly welded together between them. On the two sides of the lower casing, there are mounting elements for mounting the assembly to the roof of the vehicle cabin. On one of the sides of the module's framework and on its front part, there are cameras mounted on brackets. In the middle of the front part, a 2D lidar is mounted. On the sides of the framework, side lidars and cameras are mounted. On the protruding middle part of the frame, there is a 3D lidar mounted on an adjustable swivel bracket. In the middle of the framework, there is a computing unit.

The drawbacks of this solution include the lack of integrated sensor cleaning systems, the lack of means for protecting the computing equipment from overheating, and a large size making it possible to install the module only on large trucks.

### SUMMARY OF THE INVENTION

The problem to be solved by the proposed invention is to develop a multifunctional mobile module for automatic vehicle control.

The objective of the proposed invention is to make it possible to mount the multifuncitonal mobile module onto the roof of any vehicle to turn it into an autonomous vehicle by providing all the functions of an autopilot system within a single module, ensuring the operability of the module within a wide range of ambient temperatures (−40° C. to +50° C.), as well as within a wide range of weather conditions (rain, downpour, snow) by means of a thermal management system (TMS) and sensor cleaning systems that are integrated into the body of the module.

The objective is achieved by means of a multifunctional mobile module for automatic vehicle control, comprising an underframe (1) made of a metal profile and equipped with metal brackets that hold cameras (2,3), a lidar (4) and an outer plating, and, further, a frame (47) with a sealing loop (48) is attached to the underframe (1) by means of brackets, wherein the outer plating is comprised of a front part (53), a rear part (54), side parts (50, 51), a bottom part (49), and an upper part in the form of a hood (30) that has a lower layer (31) and an upper layer and contains car locks (61) and gas lifts (62) used to hold the hood (30) open, and plating parts, wherein a module windshield (60) is glued to the front plating part (53) that lets through a laser beam of the lidar (4), and there are sealers (52) along the perimeter of the side plating parts (50, 51) that ensure that the module is sealed during mounting and fixing of the front plating (53) and rear plating (54) parts, wherein to the side plating parts (50, 51), plating lugs (56, 57) are attached through sealers (55), to which a small front glass (58) and a small rear glass (59) are glued, and, in turn, the assembled plating forms a closed, sealed enclosure that is serviced by a thermal management system, and wherein the whole plating is made of an RF transparent composite; further, an inertial navigation system (5), calculators (14) of an automated vehicle control system, network switches (15, 16), and a hardware time synchronizer (18) are attached to the underframe (1) by means of metal brackets, wherein a Global Navigation Satellite System receiver (6) is integrated into the hood (30), and on the sides of the upper part of the underframe (1), GSM antennas (19) are mounted; further, under the GSM antennas (19), circulation fans (32) are located, with heaters (33) positioned in front of the fans (32); wherein in the central part of the underframe (1), terminal blocks (21, 22) are located, along with two DC-to-DC converters (20) with input protection from reverse polarity, protection from overload, and short circuit protection, and, in turn, the front part of the underframe (1) holds wiper blades (37), wherein the left front part of the underframe (1) holds a wiper drive (35); wherein the front plating part (53) of the underframe (1) has daytime running lamps (63), and, further, the rear right part of the underframe (1) contains a washer fluid tank (38) that can be filled up through a neck (39), and there is a pump (40) mounted near the tank (38) that supplies washer fluid via a network of tubes to injectors (41) located in the upper part of the front plating part (53), which atomize washer fluid and spray it onto the module windshield (60), further, by means of a pneumatic valve (42), air is vented onto the windshield (60) through nozzles (43) that are located near the injectors (41), thus cleaning the windshield (60) in front of the sensors; wherein the rear part of the underframe (1) contains a peripherals controller (34), supply fans (23) that blow outside air through polypropylene filters (24) to a collector (25), thus creating gage pressure there and venting the air through nozzles (26, 27) of the collector (25) of the thermal management system to radiators of the most heated devices in the module, exhaust fans (28) that exhaust the air via air ducts (29) from space between the lower (31) and the upper layers of the hood (30) through the polypropylene filters (24) outside; wherein the rear plating part (54) has stroboscopes (64) to attract attention of people around, and, further, the bottom plating part (49) has connection platforms (65) to attach the module to the vehicle; and wherein a connector panel (66) is located in a recess in the bottom plating part (49) to connect the module to an on-board power grid and to an on-board CAN bus of the vehicle.

### BRIEF DESCRIPTION OF THE DRAWINGS

FIG. 1 illustrates the configuration and positioning of all the sensors in the module. In the drawing:
1—Underframe;
2—Medium resolution camera;
3—High resolution camera;
4—Lidar;
5—Inertial navigation system;
6—Global Navigation Satellite System (GNSS) receiver;
7—Front metal bracket of the camera;
8—Front side metal bracket of the camera;
9—Rear side metal bracket of the camera;
10—Wide angle lens;
11—Narrow focus lens;
12—Bracket of the inertial navigation system.

FIG. 2 illustrates the configuration and positioning of all the equipment in the module. In the drawing:
1—Underframe;
13—Bracket of the calculators;
14—Calculator;
15—Network switch 1;
16—Network switch 2;
17—Bracket of the switches;
18—Hardware time synchronizer;
19—GSM antenna;
20—DC-to-DC converter;
21—Small terminal block;
22—Large terminal block.

FIG. 3 illustrates the configuration and positioning of the TMS, as well as its operating principles. In the drawing:
1—Underframe;
25—TMS collector;
26—Large nozzle;
27—Small nozzle;
28—Exhaust fan;
3—Circulation fan;
33 —Heater.

FIG. 4 illustrates the configuration and positioning of the TMS, as well as its operating principles. In the drawing:
23—Supply fan;
24—Polypropylene filter;
25—TMS collector;
30—Upper plating part (hood).

FIG. 5 illustrates the configuration and positioning of the TMS, as well as its operating principles. In the drawing:
24—Polypropylene filter;
25—TMS collector;
28—Exhaust fan;
29—Air duct;
30—Upper plating part (hood);
31—Lower hood layer.

FIG. 6 illustrates the configuration and positioning of the sensor cleaning systems. In the drawing:
1—Underframe;
34—Peripherals controller;
35—Wiper drive;
36—Wiper trapezoid;
37—Wiper blade;
38—Washer fluid tank;
39—Neck;
40—Pump;
41—Injectors;
42—Pneumatic valve;
43—Nozzle.

FIG. 7 illustrates the configuration of the plating and sealing loop. In the drawing:
1—Underframe;
30—Upper plating part (hood).
44—Front plating bracket;
45—Side plating bracket;
46—Rear plating bracket;
47—Frame;
48—Sealing loop;
49—Bottom plating part;
50—Right side plating part;
51—Left side plating part;
52—Sealer 1;
53—Front plating part;
54—Rear plating part;
55—Sealer 2;
56—Right plating lug;
57—Left plating lug;
58—Small front glass;
59—Small rear glass;
60—Module windshield;
61—Lock.

FIG. 8 illustrates the assembled module with an open hood. In the drawing:
29—Air duct;
62—Gas lift;
63—Headlight (daytime running lamp).

FIG. 9 illustrates the connection elements of the module. In the drawing:
64—Stroboscope;
65—Connection platforms;
66—Connector panel;
67—Quick-release fitting.

FIG. 10 illustrates fields of view of the sensors in the module.

FIG. 11 illustrates the module mounted on a vehicle.

### DETAILED DESCRIPTION OF THE INVENTION

A multifunctional mobile module for automatic vehicle control comprises an underframe (1) made of a metal profile and equipped with metal brackets that hold screw-connected sensors (cameras, a lidar, an inertial navigation system, a Global Navigation Satellite System (GNSS) receiver), equipment (calculators, fans, heaters, network switches, a peripherals controller, GSM (Global System for Mobile Communications) antennas, sensor cleaning system components), and an outer plating that is also mounted onto the underframe (1).

The sensors that provide data used for automatic vehicle control include: cameras (2,3), a lidar (4), an inertial navigation system (5), and a Global Navigation Satellite System receiver (6) (see FIG. 1).

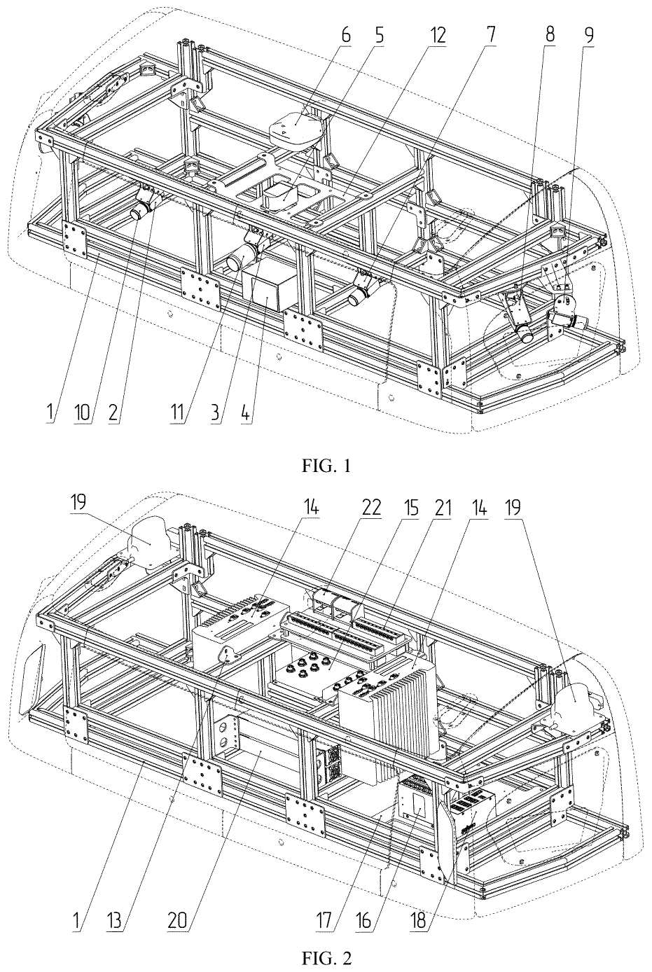

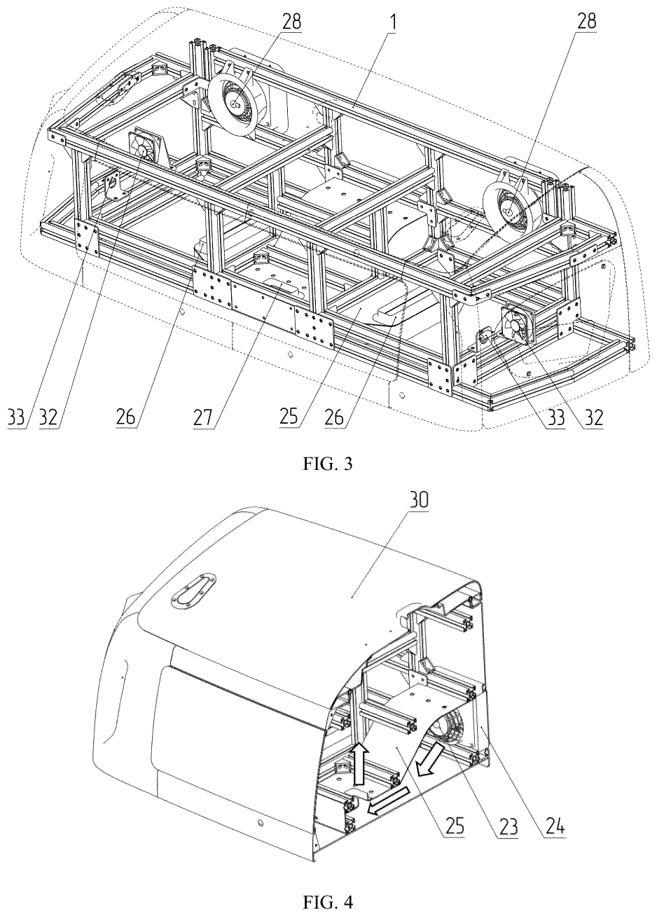

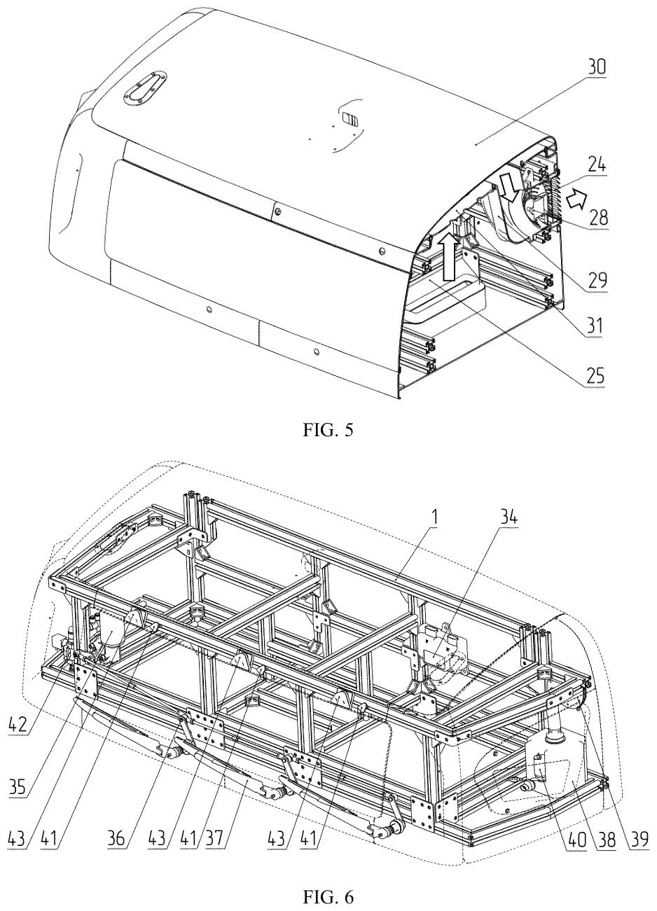

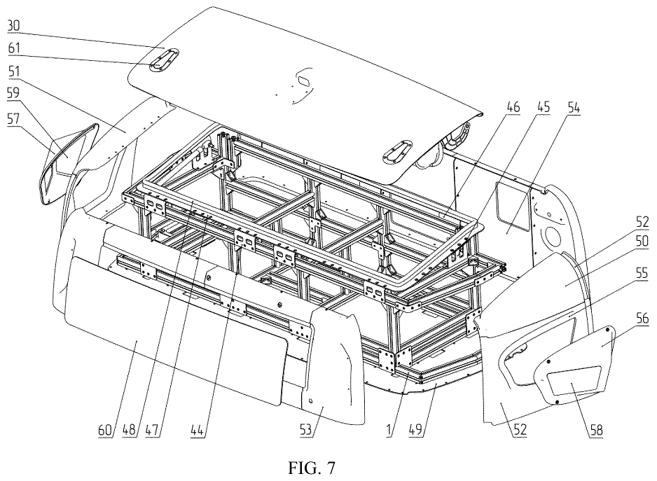

The cameras are mounted on metal brackets (7, 8, 9) using screw connections. These brackets are configured to adjust the cameras by azimuth and pitch, while also providing heat removal from the cameras. The cameras are positioned by azimuth so as to provide 360° coverage around the module and mutual overlap of the fields of view in the mounting areas (see FIG. 10). In addition, the forward-looking direction is covered by cameras with different resolution (2, 3) and different lenses (10, 11) so as to effectively detect obstacles in both the near and far ranges (see FIG. 1).

The inertial navigation system (5) is rigidly mounted on the underframe (1) by means of a bracket (12) (see FIG. 1). By mounting the lidar (4) onto the underframe (1) in the central part of the module, it is ensured that the lidar beams cover the most dangerous area in front of the vehicle (see FIG. 1).

By placing the Global Navigation Satellite System receiver (6) in the upper part of the module (integrated into the two-layer hood (30)), it is possible to minimize the loss of useful satellite signal (see FIG. 1).

The calculators (14) for processing sensor data and solving the problem of

automatic control based on these data, are mounted onto the underframe (1) by means of brackets (13). Network switches (15, 16) that provide connections for the sensors are also attached to the underframe (1). On the bracket (17), next to the network switches (16), there is a hardware time synchronizer (18), which feeds uniform time to all system components (see FIG. 2).

GSM antennas (19) are mounted on the upper sides of the underframe (1), providing the module with 4G signal (see FIG. 2).

On the bottom of the central part of the underframe (1), two DC-to-DC converters (20) are located with input protection from reverse polarity, protection from overload, and short circuit protection. Together with terminal blocks (21, 22), the DC-to-DC converters (20) form the basis of the module's power supply system (see FIG. 2).

The TMS is comprised of various fans that configured to continuously purge the module with outside air through air ducts. The supply fans (23) blow outside air through polypropylene filters (24) to the TMS collector (25), thus creating gage pressure there. The air is then vented through the nozzles (26, 27) to radiators of the most heated devices (see FIG. 3). The exhaust fans (28) exhaust the air via air ducts (29) from the space between the upper and lower layers of the hood (30) outside. Since the lower layer of the hood (31) is perforated, constant air circulation in the system is achieved (see FIGS. 4, 5). Polypropylene filters (24) are also mounted behind the exhaust fans (28) in order to prevent dust from entering the module. On the sides of the underframe (1), there are circulation fans (32) and heaters (33) in front of them (see FIG. 3).

In the front part of the underframe (1), to the left, a wiper drive (35) is mounted, which actuates the wiper trapezoid (36), to which, in turn, the wiper blades (37) are fixed (see FIG. 6).

The rear right part of the underframe (1) contains a washer fluid tank (38) that can be filled up through a neck (39). There is a pump (40) mounted near the tank (38) that supplies washer fluid via a network of tubes to injectors (41) located in the upper part of the front plating part (53), which atomize washer fluid and spray it onto the module windshield (60) (see FIG. 6).

The module is configured to connect to the compressor of an external pneumatic system via a quick-release fitting (67) and, by controlling a pneumatic valve (42) located on the left side of the underframe by means of a metal bracket, to vent air onto the windshield (60) through nozzles (43) thus cleaning the areas in front of the sensors (see FIG. 6).

All the cleaning systems, fans and heaters are controlled by the peripherals controller (34) that is located at the rear of the module's underframe.

A frame (47) with a sealing loop (48) is attached to the underframe (1) by means of brackets. The bottom plating part (49) is mounted onto the underside of the underframe (1). The side plating parts (50, 51) are mounted onto the sides of the underframe (1) via the brackets (45, 46) and the bracket (44) using a screw connection. There are sealers (52) along the perimeter of the side plating parts (50, 51) that ensure that the module is sealed during mounting and fixing of the front plating (53) and rear plating (54) parts. To the side plating parts (50, 51), plating lugs (56, 57) are attached through sealers (55), to which a small front glass (58) and a small rear glass (59) are glued. The module windshield (60) is glued to the front plating part (53) that lets through the lidar (4) laser beams. The assembled plating forms a closed, sealed enclosure that is serviced by the TMS. The assembled plating is made of an RF transparent composite, such as fiberglass (see FIG. 7).

For ease of maintenance, the hood (30) of the module can be opened (see FIG. 8). The hood (30) is equipped with car locks (61) in order to restrict the unauthorized and unqualified access to the interior of the module (see FIG. 7). For ease of maintenance, the hood (30) can be kept open by means of gas lifts (62) (see FIG. 8).

The front plating part (53) bears headlights (daytime running lamps) (63) (see FIG. 8). The rear plating part (54) has stroboscopes (64) to attract attention of the people around the vehicle (see FIG. 9).

The bottom plating part has connection platforms (65) to attach the module to the vehicle. A connector panel (66) is located in a recess in the bottom plating part to connect the module to an on-board power grid and to an on-board CAN bus of the vehicle.

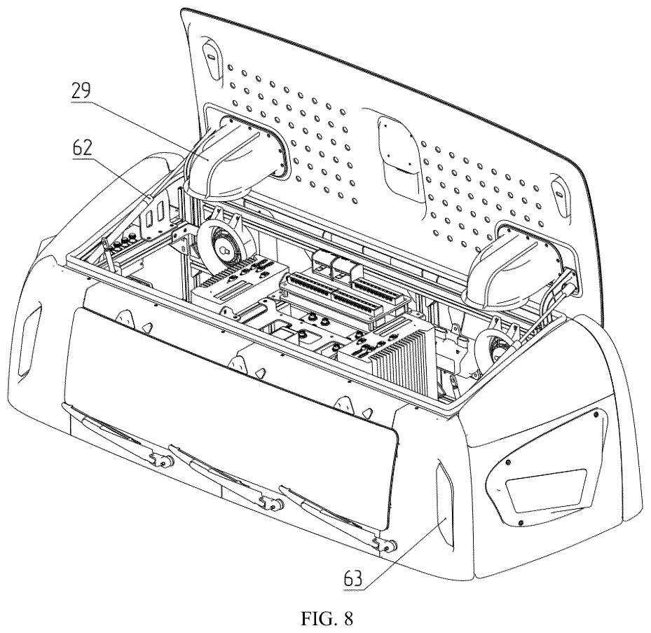

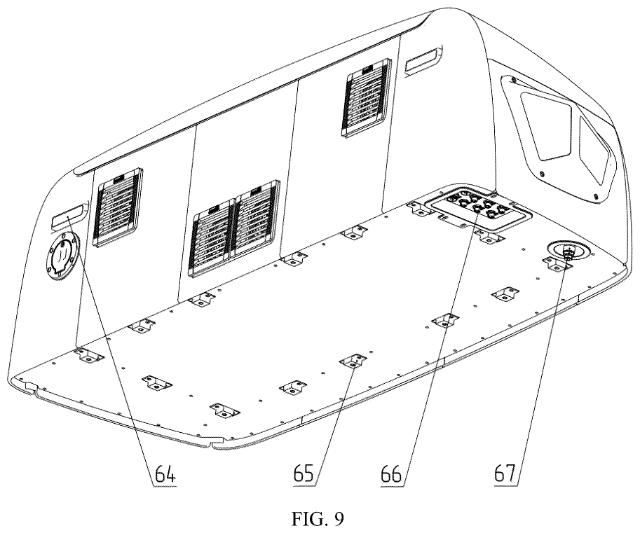

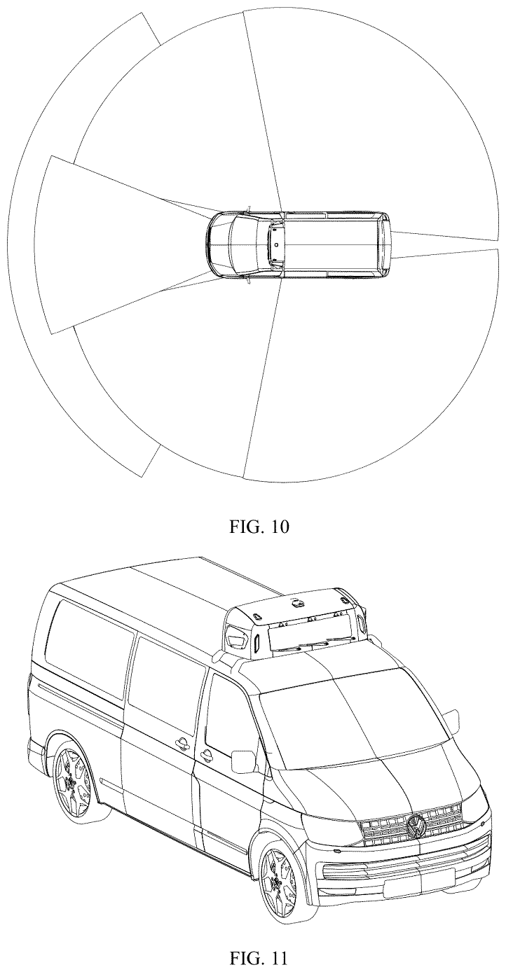

The proposed invention operates as follows. After it is mounted onto the vehicle cabin using a multipurpose strapping and connected to the on-board power grid of the vehicle and to the on-board CAN bus (with support), the module starts functioning (see FIG. 11).

The peripherals controller (34) receives information about the temperature and humidity inside the module and starts to bring it to the temperature and humidity required for the rest of the equipment to turn on (warm-up or air venting).

The air venting is performed by turning on the supply fans (23) that blow outside air to the TMS collector (25). Through the nozzles (26, 27), the air from the TMS collector (25) is vented to the radiators of devices that need cooling. Using air ducts (29), the exhaust fans (28) located on the two-layer hood (30) exhaust the air from the space between the layers of the hood to the outside, thus ensuring a complete purge of the enclosure (see FIGS. 4, 5).

When the set temperature is reached, the peripherals controller (34) turns on the rest of the module's equipment. The TMS still continues to monitor the temperature.

While the module is operating, the peripherals controller (34) receives signals from the calculator (14) about whether the sensors have become dirty, and, when necessary, activates various cleaning modes (depending on the type of dirtiness and sensors'feedback).

Thus, the proposed multifunctional module is able to perform all the functions necessary for automatic vehicle control, and the combination of the peripherals controller, the TMS, and the sensor cleaning systems ensure the module's continuous operation in every weather condition. This, as well as the minimal necessary communication with the on-board network of the vehicle and the multipurpose strapping allow the module to be mounted onto the cabin of any vehicle and, further, given access to the CAN bus, control it, or, without such access, provide the user with extended environmental information.

What is claimed is:

A multifunctional mobile module for automatic vehicle control, comprising an underframe (1) made of a metal profile and equipped with metal brackets that hold cameras (2,3), a lidar (4) and an outer plating, and, further, a frame (47) with a sealing loop (48) is attached to the underframe (1) by means of brackets, characterized in that the outer plating is comprised of a front part (53), a rear part (54), side parts (50, 51), a bottom part (49), and an upper part in the form of a hood (30) that has a lower layer (31) and an upper layer and contains car locks (61) and gas lifts (62) used to hold the hood (30) open, and plating parts, wherein a module windshield (60) is glued to the front plating part (53) that lets through a laser beam of the lidar (4), and there are sealers (52) along the perimeter of the side plating parts (50, 51) that ensure that the module is sealed during mounting and fixing of the front plating (53) and rear plating (54) parts, wherein to the side plating parts (50, 51), plating lugs (56, 57) are attached through sealers (55), to which a small front glass (58) and a small rear glass (59) are glued, and, in turn, the assembled plating forms a closed, sealed enclosure that is serviced by a thermal management system, and wherein the whole plating is made of an RF transparent composite; further, an inertial navigation system (5), calculators (14) of an automated vehicle control system, network switches (15, 16), and a hardware time synchronizer (18) are attached to the underframe (1) by means of metal brackets, wherein a Global Navigation Satellite System receiver (6) is integrated into the hood (30), and on the sides of the upper part of the underframe (1), GSM antennas (19) are mounted; further, under the GSM antennas (19), circulation fans (32) are located, with heaters (33) positioned in front of the fans (32); wherein in the central part of the underframe (1), terminal blocks (21, 22) are located, along with two DC-to-DC converters (20) with input protection from reverse polarity, protection from overload, and short circuit protection, and, in turn, the front part of the underframe (1) holds wiper blades (37), wherein the left front part of the underframe (1) holds a wiper drive (35); wherein the front plating part (53) of the underframe (1) has daytime running lamps (63), and, further, the rear right part of the underframe (1) contains a washer fluid tank (38) that can be filled up through a neck (39), and there is a pump (40) mounted near the tank (38) that supplies washer fluid via a network of tubes to injectors (41) located in the upper part of the front plating part (53), which atomize washer fluid and spray it onto the module windshield (60), further, by means of a pneumatic valve (42), air is vented onto the windshield (60) through nozzles (43) that are located near the injectors (41), thus cleaning the windshield (60) in front of the sensors; wherein the rear part of the underframe (1) contains a peripherals controller (34), supply fans (23) that blow outside air through polypropylene filters (24) to a collector (25), thus creating gage pressure there and venting the air through nozzles (26, 27) of the collector (25) of the thermal management system to radiators of the most heated devices in the module, exhaust fans (28) that exhaust the air via air ducts (29) from space between the lower (31) and the upper layers of the hood (30) through the polypropylene filters (24) outside; wherein the rear plating part (54) has stroboscopes (64) to attract attention of people around, and, further, the bottom plating part (49) has connection platforms (65) to attach the module to the vehicle; and wherein a connector panel (66) is located in a recess in the bottom plating part (49) to connect the module to an on-board power grid and to an on-board CAN bus of the vehicle.
